(19) United States
(12) Patent Application Publication
(10) Pub. No.: US 2024/0053829 A1
(43) Pub. Date: Feb. 15, 2024

(54) METHOD AND APPARATUS FOR IDENTIFYING USER INTERACTIONS

(71) Applicant: CAMBRIDGE MECHATRONICS LIMITED, Cambridge, Cambridgeshire (GB)

(72) Inventor: Marc-Sebastian Scholz, Cambridge (GB)

(21) Appl. No.: 18/270,898

(22) PCT Filed: Jan. 6, 2022
(86) PCT No.: PCT/GB2022/050020

§ 371 Date: Jul. 5, 2023

(30) Foreign Application Priority Data
Jan. 6, 2021 (GB) 2100160.7

(51) Int. Cl. G06F 3/01; H03K 17/94

(52) U.S. Cl. CPC G06F 3/016; H03K 17/94; H03K 2217/94031

(57) ABSTRACT

Broadly speaking, embodiments of the present techniques provide a method for identifying user interactions with an electronic apparatus. It is desirable to provide feedback to a user each time they interact with certain parts of the electronic apparatus. However, an actuator used to provide the feedback may interfere with a signal output by a sensor, such that it becomes difficult to identify true subsequent user interactions. The present techniques provide ways to process a raw signal output by a sensor to enable user interactions to be more easily distinguished from the interference (e.g. cross-talk).

The present techniques generally relate to a method for identifying user interactions with an electronic apparatus.

Consumer electronics devices, such as laptops and smartphones, may employ different types of controls to give users of the devices some feedback indicating that they have successfully pressed a button on the device. In some cases, this feedback may be haptic feedback that provides a tactile sensation to the user to confirm that they have successfully pressed a button/control/switch or otherwise interacted with a surface of the device. Each interaction may be detected by a sensor.

In some cases, a user may press the button on the device multiple times in a short space of time, and it may be desirable to provide feedback to the user after each button press. However, cross-talk in the signal output by the sensor, caused by the first user interaction/button press, may prevent subsequent user interactions from being detected. As a result, feedback may not be reliably provided after each user interaction.

In some cases, a user may press the button on the device once, but cross-talk in the signal output by the sensor caused by the first user interaction/button press may give rise to false user interactions. That is, the cross-talk may cause the signal output by the sensor to be interpreted as one or more further user interactions, but in reality, the user has not interacted with the button again. As a result, the actuator may be caused to actuate to deliver feedback in response to false user interactions, which may have a negative effect on user experience.

The present applicant has identified the need for an improved method for identifying real user interactions with an apparatus.

In a first approach of the present techniques, there is provided an apparatus comprising: a sensor for sensing user interaction with a surface of the apparatus; an actuator arranged to actuate in response to the sensed user interaction; and at least one processor coupled to the actuator and sensor and arranged to: identify an expected presence of cross-talk caused by actuation of the actuator in a signal originating from the sensor; in response to the identifying, remove or ignore at least some of the cross-talk from the signal; and when at least some of the cross-talk has been removed or ignored, identify a user interaction from the signal.

In other words, if cross-talk is identified within a signal originating from the sensor, the processor may take one of two actions.

Firstly, the processor may remove at least some of the cross-talk from the signal. (This may involve generating a new signal which is formed by removing at least some of the cross-talk from the original signal). Once at least some of this cross-talk has been removed, the processor may proceed to identify a user interaction with a surface of the apparatus from the signal.

Secondly, the processor may simply ignore at least some of the cross-talk. (This may not involve generating a new signal). Once at least some of this cross-talk has been ignored, the processor may proceed to identify a user interaction with a surface of the apparatus from the signal.

Another possible action is that the processor may simply reject the signal originating from the sensor entirely. In this case, the processor does not proceed to identify a user interaction with a surface of the apparatus.

Accordingly, in a second approach of the present techniques, there is provided an apparatus comprising: a sensor for sensing user interaction with a surface of the apparatus; an actuator arranged to actuate in response to the sensed user interaction; and at least one processor coupled to the actuator and sensor and arranged to: identify an expected presence of cross-talk caused by actuation of the actuator in a signal originating from the sensor; and, in response to the identifying, reject the signal.

The apparatus may be any one of: a smartphone, a protective cover or case for a smartphone, a functional cover or case for a smartphone or electronic device, a camera, a foldable smartphone, a foldable image capture device, a foldable smartphone camera, a foldable consumer electronics device, a camera with folded optics, an image capture device, an array camera, a 3D sensing device or system, a servomotor, a consumer electronic device (including domestic appliances such as vacuum cleaners, washing machines and lawnmowers), a mobile or portable computing device, a mobile or portable electronic device, a laptop, a tablet computing device, an e-reader (also known as an e-book reader or e-book device), a computing accessory or computing peripheral device (e.g. mouse, keyboard, headphones, earphones, earbuds, etc.), an audio device (e.g. headphones, headset, earphones, etc.), a security system, a gaming system, a gaming accessory (e.g. controller, headset, a wearable controller, joystick, etc.), a robot or robotics device, a medical device (e.g. an endoscope), an augmented reality system, an augmented reality device, a virtual reality system, a virtual reality device, a wearable device (e.g. a watch, a smartwatch, a fitness tracker, etc.), an autonomous vehicle (e.g. a driverless car), a vehicle, a user interface, a user interface in a vehicle, a tool, a surgical tool, a remote controller (e.g. for a drone or a consumer electronics device), clothing (e.g. a garment, shoes, etc.), a switch, dial or button (e.g. a light switch, a thermostat dial, etc.), a display screen, a touchscreen, a flexible surface, and a wireless communication device (e.g. near-field communication (NFC) device). It will be understood that this is a non-exhaustive list of possible apparatus.

In a third approach of the present techniques, there is provided a method for identifying user interactions with an apparatus comprising a sensor and an actuator, the method comprising: identifying an expected presence of cross-talk caused by actuation of the actuator in a signal originating from the sensor; responsive to the identifying, removing or ignoring at least some of the cross-talk from the signal; and when at least some of the cross-talk has been removed or ignored, identifying a user interaction from the signal.

Preferred features are set out in the appended dependent claims, and apply to the first, second and/or third techniques.

As will be appreciated by one skilled in the art, the present techniques may be embodied as a system, method or computer program product. Accordingly, present techniques may take the form of an entirely hardware embodiment, an entirely software embodiment, or an embodiment combining software and hardware aspects.

Furthermore, the present techniques may take the form of a computer program product embodied in a computer readable medium having computer readable program code embodied thereon. The computer readable medium may be a computer readable signal medium or a computer readable storage medium. A computer readable medium may be, for example, but is not limited to, an electronic, magnetic, optical, electromagnetic, infrared, or semiconductor system, apparatus, or device, or any suitable combination of the foregoing.

Computer program code for carrying out operations of the present techniques may be written in any combination of one or more programming languages, including object oriented programming languages and conventional procedural programming languages. Code components may be embodied as procedures, methods or the like, and may comprise sub-components which may take the form of instructions or sequences of instructions at any of the levels of abstraction, from the direct machine instructions of a native instruction set to high-level compiled or interpreted language constructs.

Embodiments of the present techniques also provide a non-transitory data carrier carrying code which, when implemented on a processor, causes the processor to carry out any of the methods described herein.

The techniques further provide processor control code to implement the above-described methods, for example on a general purpose computer system or on a digital signal processor (DSP). The techniques also provide a carrier carrying processor control code to, when running, implement any of the above methods, in particular on a non-transitory data carrier. The code may be provided on a carrier such as a disk, a microprocessor, CD- or DVD-ROM, programmed memory such as non-volatile memory (e.g. Flash) or read-only memory (firmware), or on a data carrier such as an optical or electrical signal carrier. Code (and/or data) to implement embodiments of the techniques described herein may comprise source, object or executable code in a conventional programming language (interpreted or compiled) such as C, or assembly code, code for setting up or controlling an ASIC (Application Specific Integrated Circuit) or FPGA (Field Programmable Gate Array), or code for a hardware description language such as Verilog® or VHDL (Very high speed integrated circuit Hardware Description Language). As the skilled person will appreciate, such code and/or data may be distributed between a plurality of coupled components in communication with one another. The techniques may comprise a controller which includes a microprocessor, working memory and program memory coupled to one or more of the components of the system.

It will also be clear to one of skill in the art that all or part of a logical method according to embodiments of the present techniques may suitably be embodied in a logic apparatus comprising logic elements to perform the steps of the above-described methods, and that such logic elements may comprise components such as logic gates in, for example a programmable logic array or application-specific integrated circuit. Such a logic arrangement may further be embodied in enabling elements for temporarily or permanently establishing logic structures in such an array or circuit using, for example, a virtual hardware descriptor language, which may be stored and transmitted using fixed or transmittable carrier media.

In an embodiment, the present techniques may be implemented using multiple processors or control circuits. The present techniques may be adapted to run on, or integrated into, the operating system of an apparatus.

In an embodiment, the present techniques may be realised in the form of a data carrier having functional data thereon, said functional data comprising functional computer data structures to, when loaded into a computer system or network and operated upon thereby, enable said computer system to perform all the steps of the above-described method.

Implementations of the present techniques will now be described, by way of example only, with reference to the accompanying drawings, in which:

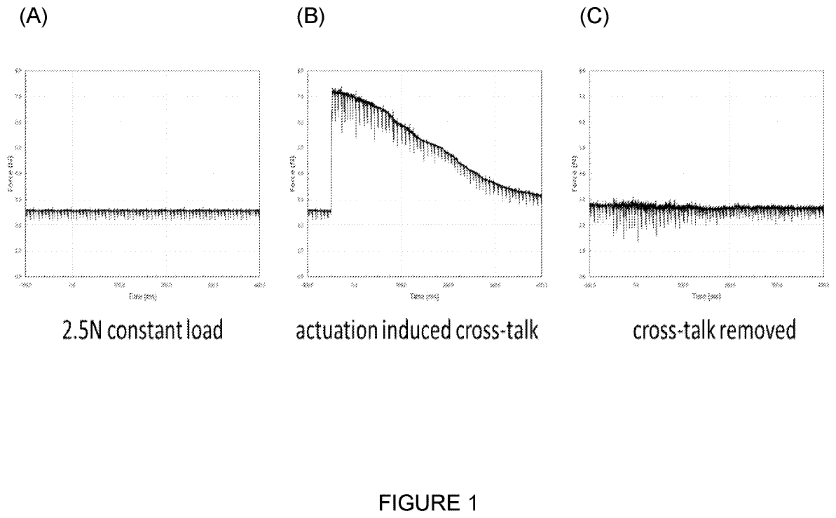

FIGS. 1A to 1C respectively show signals output by a force resistive sensor in response to a load, after actuation of an actuator to provide feedback, and after removal of cross-talk;

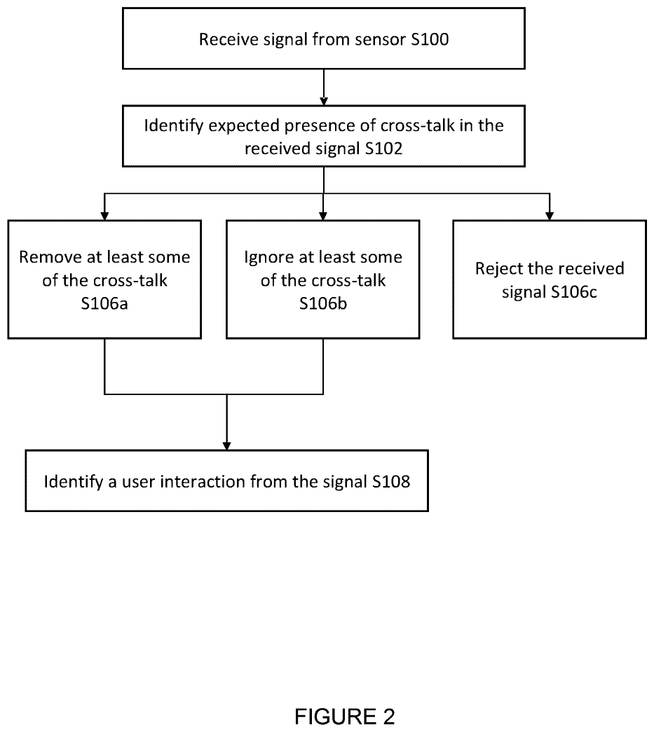

FIG. 2 is a flowchart of example steps to identify a user interaction from a raw signal output by a sensor; and

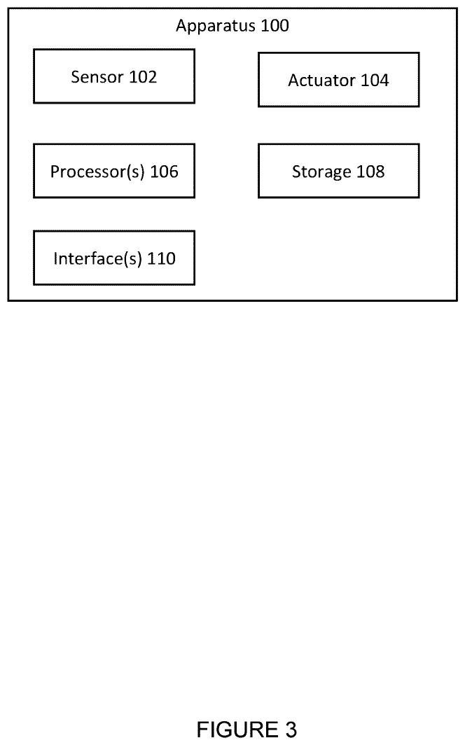

FIG. 3 is a block diagram of an apparatus comprising a sensor and actuator.

Broadly speaking, embodiments of the present techniques provide a method for identifying user interactions with an electronic apparatus, by removing cross-talk introduced into a signal output by a sensor by the actuation of an actuator that is coupled to the sensor. It is desirable to provide feedback to a user each time they interact with the electronic apparatus, or with certain parts of the electronic apparatus (e.g. a button), and the feedback may be provided by causing an actuator to actuate to deliver a tactile sensation to the user. In some cases, the user interaction may be on a part of the electronic apparatus that contains the sensor that can sense the user interaction. For example, the sensor may be a touch-sensitive sensor, and the feedback may therefore be in response to the sensor sensing the user's touch. In some cases, a software application with which the user is interacting may send a signal to the actuator to cause the actuator to actuate to provide the feedback. For example, the user may be playing a game on the apparatus and the game may provide the user with some information by providing the tactile sensation to the user. However, in all cases, the actuation of the actuator may interfere with the signal output by the sensor, such that it becomes difficult to identify subsequent user interactions or such that false user interactions are suggested, because the sensor and actuator are coupled. Thus, the present techniques provide a way of removing this interference, so that the sensor signal can be used to identify contact- or proximity-based user interactions more reliably and accurately.

FIGS. 1A and 1B illustrate the problem of interference or cross-talk. An apparatus may comprise a sensor for sensing user interaction with a surface of the apparatus. The interaction may be with a button or a specific area of the apparatus. The apparatus may comprise an actuator arranged to actuate in response to the sensed user interaction. In some cases, the actuator may be caused to actuate by a software application running on the apparatus, and with which the user is interacting (e.g. a game). In some cases, software and/or hardware may send a signal to actuate the actuator to indicate to the user that they need to lift their finger off a surface or off a button, because the user has pressed the button for too long. Examples of how feedback may be provided in response to different events or user actions can be found in United Kingdom Patent Publication No. GB2578454. Thus, the actuator may actuate in response to a feedback trigger, which may be based on an interaction with the user with some hardware component of the apparatus, or an interaction with the user with some software on the apparatus, or by some software and/or hardware that is coupled to the actuator and/or the sensor.

Providing the tactile feedback may be desirable in a number of contexts, such as in a medical device used to perform a surgical procedure, or in a games controller used to play a computer game.

FIG. 1A shows how a sensor may respond to the application of a load to a button or surface of the apparatus. In this example, the sensor is a force resistive sensor, and the actuator is a shape memory alloy (SMA) actuator. It will be understood that the signals may take a different form for other types of sensor and actuator. When a user applies a constant force to the surface of the apparatus, the sensor outputs a substantially constant signal indicative of the user interaction. This can be used by a processor, controller or control electronics to determine that the actuator needs to be actuated to provide the required feedback to the user. However, when the actuator is actuated, the signal output by the sensor may be impacted, as shown in FIG. 1B. The cross-talk induced by the actuation of the actuator can be seen to cause a sharp spike in the signal output by the sensor, followed by a gradual decrease in amplitude. Of course, it will be understood that the cross-talk caused by the actuation of the actuator may present in different forms/ways, and that FIG. 1B shows an example of cross-talk only. Since the sensor and actuator are coupled within the apparatus, actuation of the actuator that is triggered by events not sensed by the sensor may still cause cross-talk within the signal output by the sensor. The nature of the cross-talk in the signal output by the sensor may vary depending on whether the sensor has sensed a user interaction and caused the actuator to actuate, or whether the actuator has actuated in response to another trigger.

The cross-talk introduced in the sensor signal means it is difficult, for some time, to determine any subsequent user interactions with the surface of the apparatus. This can be problematic in cases where multiple user interactions may be received in quick succession, such as may be the case when a user is using a gaming controller, a smartphone, or surgical (robotic) device. User interactions may also take different forms. For example, a user may press a button or apply a force to a surface of the apparatus, and may either release the button/remove the force immediately or may hold the button down/apply the force for a longer time—short button presses and long button presses may be used to interact with the apparatus in different ways or to implement different functions of the apparatus. Similarly, a change in force applied to the surface of the apparatus may be used to determine that a user has depressed or released a button—this may be useful to know as it may be used to determine when the feedback to the user can be stopped, for example. A user may press a button multiple times in the same way that a mouse button can be pressed once or used to ‘double-click’. It is therefore desirable to correctly identify how the user has interacted with the surface of the apparatus, so that the correct feedback can be provided to the user (and so that the correct functions of the apparatus are initiated in response to specific types of user interaction).

FIG. 1C shows the sensor signal after the cross-talk has been removed. It is now easier to identify any further button presses/user interactions, or determine whether a button press is a long or short press, or when a button press is released, and so on. The present techniques therefore solve the problem of false events (e.g. press, release, short press, double click, etc.) being observed in the sensor signal when no event/user interaction took place in reality by a processor, controller or control electronics due to actuator induced crosstalk in the sensor signal on actuation.

FIG. 2 is a flowchart of example steps to identify a user interaction from a raw signal output by a sensor. The method may begin by receiving a signal from the sensor (step S100). The method may comprise identifying an expected presence of cross-talk caused by actuation of the actuator in the signal originating from the sensor (step S102). Identifying the expected presence of the cross-talk may comprise receiving a signal indicative of an actuation of the actuator.

If cross-talk is identified within a signal originating from the sensor, the processor may take one of three actions.

One possible action is that the processor may remove at least some of the cross-talk from the signal (step S106a). This may involve generating a new signal which is formed by removing at least some of the cross-talk from the original signal. Once at least some of this cross-talk has been removed from the (original/received) signal, the processor may proceed to identify a user interaction with a surface of the apparatus from the generated signal (step S108).

Another possible action is that the processor may simply ignore at least some of the cross-talk in the signal (step S106b). This may not involve generating a new signal, but simply ignoring at least some parts of the received/original signal which correspond to cross-talk. Once at least some of this cross-talk has been ignored from the signal, the processor may proceed to identify a user interaction with a surface of the apparatus from the signal (step S108).

Another possible action is that the processor may simply reject the signal originating from the sensor entirely (step S106c). In this case, the processor does not proceed to identify a user interaction with a surface of the apparatus. Instead, the processor awaits a further signal from the sensor.

In some cases the raw signal output by the sensor which contains cross-talk may be processed before performing steps S106a, S106b or S106c to enable a user interaction to be more clearly identified. For example, the received (raw) signal from the sensor may be subjected to at least one of: convolution, integration, differentiation, and filtering. The processed signal may enable a user interaction to be more easily identified than from the raw received signal (step S204).

In some cases, it may be assumed that there is always cross-talk (caused by the actuation of the actuator) present in the raw signal output by the sensor. In other cases, cross-talk caused by the actuation of the actuator may be identified by analysing the raw signal and identifying something that may be indicative of cross-talk. The cross-talk that is caused by actuation of the actuator may be considered “dynamic cross-talk”, because it appears in response to actuation of the actuator. Other cross-talk may be present in the signal that has not been caused by actuation of the actuator—such cross-talk may or may not be removed by the present techniques. For example, non-dynamic cross-talk that is not caused by the actuation of the actuator may always be present, or may be periodic in nature. This non-dynamic cross-talk may be removed or compensated for by a filtering operation (e.g. by performing a simple subtraction of the noise or cross-talk from the signal output by the sensor). Once the dynamic cross-talk has been identified, the method may then remove or ignore at least some of the part of the cross-talk caused by actuation of the actuator from the signal, or may simply reject the signal entirely (i.e. not process the signal any further to identify a user interaction). It may not be possible to fully remove the dynamic cross-talk (because of the presence of signal noise), but a significant portion of the cross-talk may be removed or ignored from the signal that enables subsequent user interactions to be observed from the signal output by the sensor.

The removal of at least some of the cross-talk caused by actuation of the actuator may be possible in an apparatus or system in which such cross-talk is predictable and repeatable (i.e. the cross-talk occurs every time an actuator actuates, and the nature of the cross-talk is substantially the same each time). In such apparatuses/systems, the cross-talk correction may be applied to the sensor signal prior to input to an analogue-to-digital converter. This may enable the apparatus to simultaneously provide feedback in response to sensing a user interaction, and sense subsequent user interactions. This may improve user experience. In some cases, hardware may be used in addition to, or instead of software, to remove the cross-talk.

Removing or ignoring at least some of the cross-talk may comprise determining an expected cross-talk signal. Determining the expected cross-talk signal may comprise using a function to model the cross-talk. The function may take as an input any one or more of: actuation pulse length, actuation pulse duration, actuation pulse duration, internal temperature, external temperature, force, and force applied to the surface of the apparatus.

Determining the expected cross-talk signal may comprise obtaining at least one input for the function from a drive signal used to actuate the actuator. Additionally or alternatively, determining the expected cross-talk signal may comprise obtaining at least one input for the function from the sensor. Additionally or alternatively, determining the expected cross-talk signal may comprise retrieving, from storage, a pre-determined cross-talk signal. Optionally, the pre-determined cross-talk signal may be determined during calibration of the sensor and actuator.

In a particular embodiment, to remove a substantial amount of the dynamic cross-talk, it is necessary to have determined the nature of the dynamic cross-talk caused by actuation of the actuator—e.g. the shape of the cross-talk signal, a mathematical function that approximates the cross-talk signal, the length of time the cross-talk is present within the signal, the amplitude of the cross-talk signal, and so on. By way of an example, an apparatus may comprise a force resistive sensor and a shape memory alloy haptic actuator. In such an apparatus, it has been shown that dynamic cross-talk in the sensor signal is dependent on the force applied by the user to the surface of the apparatus, the drive signal of actuation, and temperature. Knowledge of the state of these variables at the point of actuation enables the dynamic cross-talk to be modelled.

The method to remove cross-talk may comprise applying a function modelling the cross-talk caused by actuation of the actuator to the raw signal, to remove at least some of the part of the cross-talk caused by actuation of the actuator from the raw signal. The function may take as an input any one or more of: actuation pulse length, actuation pulse duration, actuation pulse duration, internal temperature, external temperature, force, and force applied to the surface of the apparatus. The processor may obtain at least one input for the function from a drive signal used to actuate the actuator and/or from an internal or external sensor.

Alternatively, the method may comprise retrieving a pre-determined cross-talk signal that is caused by actuation of the actuator, which may be determined during calibration of the sensor and actuator (by modelling or otherwise). The user may also recalibrate the sensor and actuator at any time, which may be necessary after some time or some number of uses of both the actuator and sensor. The cross-talk signal determined during this re-calibration may be stored as the new pre-determined cross-talk signal to be used to compensate for or remove at least some of the dynamic cross-talk.

The step of removing at least the part of the cross-talk that is caused by actuation of the actuator may comprise subtracting the pre-determined/expected cross-talk signal from the signal originating from the sensor. The method may further comprise adding a baseline signal to the signal originating from the sensor. Both the subtraction of the expected/pre-determined cross-talk from the sensor signal, and the addition of the baseline, is performed from the point at which the actuator is actuated.

The step of removing the part of the cross-talk from the signal output by the sensor is performed in real-time to enable further user interactions to be sensed. Advantageously, this enables sensing and actuation to be performed concurrently.

It is advantageous to remove cross-talk from the sensor signal during the times when cross-talk is expected (and during which, false events or user interactions may be identified, or real user interactions may be missed). Cross-talk that is caused by actuation of the actuator is most likely to be observed after actuation. For example, in response to a first button press, haptic feedback may be delivered by the actuator over a period, T. If the cross-talk in the sensor during this period is not removed, subsequent button presses that occur within the period T may not be identified. Similarly, due to the cross-talk in the signal, false user interactions may be determined during period T. Thus, the step of removing the part of the cross-talk from the signal output by the sensor may comprise removing the part of the cross-talk during a pre-defined period after the actuator is actuated. The pre-defined period may be equal to the period T during which the actuator is actuated, or may be shorter than this period (i.e. T−dt) or may be longer than this period (i.e. T+dt).

Alternatively, the impact of the cross-talk may be removed by simply ignoring the sensor reading for a pre-defined period after the actuator is actuated. The pre-defined period may be equal to the period T during which the actuator is actuated, or may be shorter than this period (i.e. T−dt) or may be longer than this period (i.e. T+dt). In other words, the sensor signal may be blocked during this pre-defined period, such that no user interactions are identifiable in this pre-defined period.

FIG. 3 is a block diagram of an apparatus 100. The apparatus 100 may be any one of: a consumer electronics device (e.g. a smartphone), a medical device, and a robotics device. It will be understood this is a non-exhaustive list of example apparatuses.

The apparatus 100 comprises a sensor 102 for sensing user interaction with a surface of the apparatus 100. The sensor 102 may be any one of: a force sensor, a pressure sensor, an ultrasonic sensor, an optical sensor, a fingerprint sensor, an inductive sensor, a piezoelectric sensor, and a contact sensor. It will be understood this is a non-exhaustive list of example sensors.

The apparatus 100 comprises an actuator 104 coupled to the sensor 102 and arranged to actuate in response to a feedback trigger. The actuator 104 may be a haptics actuator arranged to deliver a tactile sensation to the user in response to the sensed user interaction. The haptics actuator may be any one of: a shape memory alloy (SMA) actuator; a piezoelectric actuator, a linear resonant actuator (LRA), and an electroactive polymer actuator. It will be understood this is a non-exhaustive and non-limiting list of possible types of haptics actuators. Examples of shape memory alloy haptic actuators can be found in International Patent Publication No. WO2019/162708.

The apparatus may comprise at least one processor, controller or control electronics 106 coupled to the actuator 104 and sensor 102. The at least one processor 106 may be arranged to: identify an expected presence of cross-talk caused by actuation of the actuator 104 (i.e. the dynamic cross-talk) in a signal originating from the sensor 102; and responsive to the identifying, removing or ignoring at least some of the part of the cross-talk in the signal, or rejecting the signal entirely. In the case where the cross-talk is removed or ignored, the processor 106 may identify a user interaction from the signal.

The processor 106 may be a dedicated processor arranged to receive and analyse a signal output by sensor 102 and transmit drive signals to the actuator 104 if a user interaction is identified in the signal. Alternatively, the processor 106 may be used to perform other functions of the apparatus (e.g. any apparatus functions that are to be performed in response to the user interaction). The processor may comprise one or more of: a microprocessor, a microcontroller, and an integrated circuit.

The feedback trigger may be a user interaction with the surface of the apparatus 100, which may be sensed by sensor 102. The feedback trigger may be a software trigger initiated by a software application running in the apparatus 100. For example, the actuator 100 may be caused to actuate by a software application running on the apparatus, and with which the user is interacting (e.g. a game). The feedback trigger may be produced by software and/or hardware within apparatus 100, which may send a signal to actuate the actuator 104 to indicate to the user that they need to lift their finger off a surface or off a button, because the user has pressed the button for too long. This feedback trigger could also be produced by sensor 102. Thus, the feedback trigger may be based on an interaction with the user with some hardware component of the apparatus, or by the sensor 102, or an interaction with the user with some software on the apparatus, or by some software and/or hardware that is coupled to the actuator 102 and/or the sensor 104.

The apparatus 100 may comprise storage 108. The storage 108 may comprise a volatile memory, such as random access memory (RAM), for use as temporary memory, and/or non-volatile memory such as Flash, read only memory (ROM), or electrically erasable programmable ROM (EEPROM), for storing data, programs, or instructions, for example.

The processor 106 may retrieve, from storage 108, a pre-determined/expected cross-talk signal that is caused by actuation of the actuator 104, determined during calibration of the sensor and actuator.

The apparatus 100 may comprise at least one user interface 110, such as a display screen. The user interface 110 may receive a user input for re-calibration of the sensor 102 and actuator 104. In response, the processor may perform the re-calibration, and may store the new pre-determined/expected cross-talk signal determined during the re-calibration in storage 108, to be used in subsequent cross-talk removal processes.

The processor 106 may remove at least some of the part of the cross-talk that is caused by actuation of the actuator 104 by subtracting the pre-determined cross-talk signal from the signal output by the sensor 102. The processor 106 may add a baseline signal to the signal output by the sensor 102.

As mentioned above, the processor 106 may remove at least some of the part of the cross-talk from the signal output by the sensor 102 in real-time to enable further user interactions to be sensed, and to avoid false user interactions from being determined.

The processor 106 may remove at least some of the part of the cross-talk from the signal output by the sensor 102 during a pre-defined period after the actuator 104 is actuated (i.e. after the actuation has begun).

Those skilled in the art will appreciate that while the foregoing has described what is considered to be the best mode and where appropriate other modes of performing present techniques, the present techniques should not be limited to the specific configurations and methods disclosed in this description of the preferred embodiment. Those skilled in the art will recognise that present techniques have a broad range of applications, and that the embodiments may take a wide range of modifications without departing from any inventive concept as defined in the appended claims.

1. An apparatus comprising:
a sensor for sensing user interaction with a surface of the apparatus;
an actuator coupled to the sensor and arranged to actuate in response to a feedback trigger; and
at least one processor coupled to the actuator and sensor and arranged to:
identify an expected presence of cross-talk caused by actuation of the actuator in a signal originating from the sensor;
in response to the identifying, remove or ignore at least some of the cross-talk from the signal; and
when at least some of the cross-talk has been removed or ignored, identify a user interaction from the signal.

2. The apparatus as claimed in claim 1, wherein identifying the expected presence of the cross-talk comprises receiving a signal indicative of an actuation of the actuator.

3. (canceled)

4. The apparatus as claimed in claim 1, wherein the feedback trigger is: a user interaction with the surface of the apparatus, sensed by the sensor; or a software trigger initiated by a software application running in the apparatus.

5. The apparatus as claimed in claim 1, wherein removing or ignoring at least some of the cross-talk comprises determining an expected cross-talk signal.

6. The apparatus as claimed in claim 5, wherein determining the expected cross-talk signal comprises using a function to model the cross-talk.

7. The apparatus as claimed in claim 6, wherein the function takes as an input any one or more of: actuation pulse length, actuation pulse duration, internal temperature, external temperature, force, and force applied to the surface of the apparatus.

8. (canceled)

9. The apparatus as claimed in claim 6, wherein determining the expected cross-talk signal comprises:
obtaining at least one input for the function from a drive signal used to actuate the actuator; and/or
obtaining at least one input for the function from the sensor.

10. The apparatus as claimed in claim 6, wherein:
determining the expected cross-talk signal comprises retrieving, from storage, a pre-determined cross-talk signal; and
the pre-determined cross-talk signal is determined during calibration of the sensor and actuator.

11. The apparatus as claimed in claim 10, further comprising:
a user interface for receiving a user input for re-calibration of the sensor and actuator; and
wherein the at least one processor is configured to store the pre-determined cross-talk signal determined during the re-calibration.

12. The apparatus as claimed in claim 5, wherein removing at least some of the cross-talk comprises subtracting the expected cross-talk signal from the signal originating from the sensor.

13. The apparatus as claimed in claim 12, wherein removing at least some of the cross-talk further comprises adding a baseline signal to the signal originating from the sensor.

14. (canceled)

15. The apparatus as claimed in claim 1, wherein:
the removal of at least some of the cross-talk is performed in real-time to enable further user interactions to be sensed; and/or
the removal of at least some of the cross-talk is performed during a pre-defined period after the actuator is actuated.

16. The apparatus as claimed in claim 1, wherein removing at least some of the cross-talk comprises blocking or ignoring the signal during a pre-defined period after the actuator is actuated.

17. The apparatus as claimed in claim 1, wherein:
the processor is configured to process the signal before removing or ignoring at least some of the cross-talk; and
processing the signal comprises performing at least one of: convolution, integration, differentiation, and filtering.

18. The apparatus as claimed in claim 1, wherein the sensor is any one of: a force sensor, a pressure sensor, an ultrasonic sensor, an optical sensor, a fingerprint sensor, an inductive sensor, a piezoelectric sensor, and a contact sensor.

19. (canceled)

20. The apparatus as claimed in claim 1, wherein the actuator is a haptics actuator that is any one of: a shape memory alloy actuator, a piezoelectric actuator, a linear resonant actuator, and an electroactive polymer actuator.

21. A method for identifying user interactions with an apparatus comprising a sensor and an actuator coupled to the sensor, the method comprising:
identifying an expected presence of cross-talk caused by actuation of the actuator in a signal originating from the sensor;
in response to the identifying, removing or ignoring at least some of the cross-talk from the signal; and
when at least some of the cross-talk has been removed or ignored, identifying a user interaction from the signal.

22. The method as claimed in claim 21, wherein identifying the expected presence of the cross-talk comprises receiving a signal indicative of an actuation of the actuator.

23. (canceled)

24. The method as claimed in claim 21, wherein removing or ignoring at least some of the cross-talk comprises:
determining an expected cross-talk signal; and
subtracting the expected cross-talk signal from the signal originating from the sensor.

25. A non-transitory data carrier carrying processor control code to implement a method for identifying user interactions with an apparatus comprising a sensor and an actuator coupled to the sensor, the method comprising:
identifying an expected presence of cross-talk caused by actuation of the actuator in a signal originating from the sensor;
in response to the identifying, removing or ignoring at least some of the cross-talk from the signal; and
when at least some of the cross-talk has been removed or ignored, identifying a user interaction from the signal.
